(19) United States
(12) Patent Application Publication
(10) Pub. No.: US 2007/0108479 A1
(43) Pub. Date: May 17, 2007

(54) RESISTANCE ELEMENT HAVING REDUCED AREA

(76) Inventor: Yoichi Okumura, Nerima-ku (JP)

Correspondence Address: TEXAS INSTRUMENTS INCORPORATED, P O BOX 655474, M/S 3999, DALLAS, TX, 75265, US

(21) Appl. No.: 11/556,427

(22) Filed: Nov. 3, 2006

(30) Foreign Application Priority Data
Nov. 4, 2005 (JP) 2005-320908

(51) Int. Cl. H01L 29/80; H01L 31/112

(52) U.S. Cl. 257/273

(57) ABSTRACT

A semiconductor device having reduced area occupied by the semiconductor elements that constitute the semiconductor device, and its manufacturing method. Insulating film 12 is formed on substrate 10. First resistance element 18b is formed on insulating film 12. Second resistance element 21b is laminated on first resistance element i8b. In particular, the first resistance element 18b and second resistance element 21b include layers shared with the layer that constitutes the gate electrode (gate electrode 18a) of the field-effect transistor or emitter-forming layer 21a containing an electroconductive impurity and used to form the emitter of the bipolar transistor.

### FIELD OF THE INVENTION

The present invention pertains to a semiconductor device and its manufacturing method. In particular, the present invention pertains to a semiconductor device that has resistance elements and transistors formed on a substrate, and its manufacturing method.

### BACKGROUND OF THE INVENTION

Active elements, such as field-effect transistors and bipolar transistors, and passive elements, such as resistance elements, capacitors, and inductors, are used as basic elements to constitute semiconductor devices.

For a resistance element, for example, the main body is constituted with a semiconductor layer made of polysilicon, and output electrodes are formed at the two ends of the semiconductor layer.

When formation of the semiconductor layer that constitutes the aforementioned resistance element is included in the step of manufacturing a field-effect transistor in order to simplify the manufacturing process, a method is known for forming the semiconductor layer with a layer shared with the gate electrode of the field-effect transistor. The aforementioned manufacturing method is described in Japanese Kokai Patent Application No. 2005-236 105. Since the aforementioned resistance element occupies a large area, it is desired to reduce the area in order to accelerate development of fine-scale semiconductor devices.

The problem to be solved is the difficulty of reducing the area occupied by the resistance element that constitutes the semiconductor device.

### SUMMARY OF THE INVENTION

In order to solve the aforementioned problem, the present invention provides a semiconductor device having an insulating film formed on a substrate, a first resistance element formed on the aforementioned insulating film, and a second resistance element laminated on the aforementioned first resistance element. Preferably, transistors are formed in the semiconductor region of said substrate of the semiconductor device disclosed in the present invention. The aforementioned first and second resistance elements include layers shared with the respective layers constituting the aforementioned transistors. More preferably, a field-effect transistor and a bipolar transistor are formed as the aforementioned transistors in the semiconductor region of said substrate of the semiconductor device disclosed in the present invention. The aforementioned first resistance element includes a layer shared with the layer that constitutes the gate electrode of the aforementioned field-effect transistor. The aforementioned second resistance element includes a layer shared with the emitter-forming layer doped with an electroconductive impurity and used to form the emitter of the aforementioned bipolar transistor.

Still more preferably, a first bipolar transistor and a second bipolar transistor are formed in the semiconductor region of the aforementioned substrate of the semiconductor device disclosed in the present invention. The aforementioned first resistance element includes a layer shared with the first emitter-forming layer doped with an electroconductive impurity and used to form the emitter of the first bipolar transistor. The aforementioned second resistance element includes a layer shared with the second emitter-forming layer doped with an electroconductive impurity and used to form the emitter of the second bipolar transistor.

Also, in order to solve the aforementioned problem, the present invention provides a semiconductor device manufacturing method having a step for forming an insulating film on a substrate, a step for forming a first resistance element on the aforementioned insulating film, and a step for laminating a second resistance element on the aforementioned first resistance element.

Preferably, the semiconductor device manufacturing method of the present invention also has a step for forming transistors in the semiconductor region of the aforementioned substrate, and in the steps for forming the aforementioned first and second resistance elements, the resistance elements are formed to include layers shared with the respective layers constituting the aforementioned transistors. More preferably, the step for forming the aforementioned transistors in the semiconductor device manufacturing method of the present invention includes a step for forming a field-effect transistor in the semiconductor region of the aforementioned substrate and a step for forming a bipolar transistor in the aforementioned semiconductor region. In the step for forming the aforementioned first resistance element, the resistance element is formed to include a layer shared with the layer constituting the gate electrode of the aforementioned field-effect transistor. In the step for forming the aforementioned second resistance element, the resistance element is formed to include a layer shared with the emitter-forming layer doped with an electroconductive impurity and used to form the emitter of the aforementioned bipolar transistor.

Still more preferably, the semiconductor device manufacturing method of the present invention also has a step for forming a first bipolar transistor in the semiconductor region of the aforementioned substrate and a step for forming a second bipolar transistor in the aforementioned semiconductor region. In the step for forming the first resistance element, the resistance element is formed to include a layer shared with the layer constituting the first emitter-forming layer doped with an electroconductive impurity and used to form the emitter of the first bipolar transistor. In the step for forming the second resistance element, the resistance element is formed to include a layer shared with the layer constituting the second emitter-forming layer doped with an electroconductive impurity and used to form the emitter of the second bipolar transistor.

### BRIEF DESCRIPTION OF THE DRAWINGS

FIG. 1 is a cross section of the semiconductor device disclosed in the first embodiment of the present invention.

FIG. 2A is an enlarged cross section of the main part (resistance element region) in FIG. 1. FIG. 2B is a plan view of the region corresponding to FIG. 2A.

FIG. 3 is a cross section illustrating the process of manufacturing the semiconductor device disclosed in the first embodiment of the present invention.

FIG. 4 is a cross section illustrating the process of manufacturing the semiconductor device disclosed in the first embodiment of the present invention.

FIG. 5 is a cross section illustrating the process of manufacturing the semiconductor device disclosed in the first embodiment of the present invention.

FIG. 6 is a cross section illustrating the process of manufacturing the semiconductor device disclosed in the first embodiment of the present invention.

FIG. 7 is a cross section illustrating the process of manufacturing the semiconductor device disclosed in the first embodiment of the present invention.

FIG. 8 is a cross section illustrating the process of manufacturing the semiconductor device disclosed in the first embodiment of the present invention.

FIG. 9 is a cross section illustrating the process of manufacturing the semiconductor device disclosed in the first embodiment of the present invention.

FIG. 10 is a cross section illustrating the process of manufacturing the semiconductor device disclosed in the first embodiment of the present invention.

FIG. 11A is a plan view of the main part (resistance element region) of the semiconductor device disclosed in the second embodiment of the present invention. FIG. 11B is the equivalent circuit diagram.

FIG. 12A is a plan view of the main part (resistance element region) of the semiconductor device disclosed in the third embodiment of the present invention. FIG. 12B is the equivalent circuit diagram.

FIG. 13A is a plan view of the main part (resistance element region) of the semiconductor device disclosed in the fourth embodiment of the present invention. FIG. 13B is the equivalent circuit diagram.

FIG. 14A is a plan view of the main part (resistance element region) of the semiconductor device disclosed in the fifth embodiment of the present invention. FIG. 14B is the equivalent circuit diagram.

FIG. 15 is an enlarged cross section of the main part (resistance element region) of the semiconductor device disclosed in the sixth embodiment of the present invention.

### REFERENCE NUMERALS AND SYMBOLS AS SHOWN IN THE DRAWINGS

In the figures, 10 represents a semiconductor substrate, 11 represents an epitaxial semiconductor layer, 12 represents an element isolation film, 13 represents an element separating layer, 14 represents a N˜buried layer, 15 represents a N˜type plug, 16 represents a P type semiconductor layer, 17 represents a gate insulating film, 18a represents a gate electrode, 18b represents a first resistance element, 19 represents a P-type semiconductor layer, 20a represents a Insulating film below emitter-forming layer, 20b represents an insulating film between resistance elements, 20c represents a Gate/emitter isolation film, 20d represents an insulating film between resistance elements, 20e represents an opening, 21a represents an emitter-forming layer, 21b represents a second resistance element, 21c represents a first resistance element, 21d represents a second resistance element, 22 represents a film for sidewall insulating, 23a represents a sidewall insulating film, 23b represents a sidewall insulating film, 24a represents a sidewall insulating film, 24b represents a sidewall insulating film, 25 represents a silicide blocking layer, 26 represents a p˜type semiconductor layer, 27 represents a p˜type semiconductor layer, 28 represents a N˜type semiconductor layer, 29 represents a silicide layer, 30 represents an interlayer insulating film, 31a, 31brepresents an upper wiring, 32a, 32b represents an upper wiring, 33a, 33b represents an Upper wiring, (FET) represents a MOSFET, (BTR) represents a Bipolar transistor, (RE) represents a resistance element, R1 represents a resistance element, R2 represents a second resistance element, R3 represents a third resistance element, R4 represents a fourth resistance element, CT18b, CT21b represents a contact hole.

### DESCRIPTION OF THE EMBODIMENTS

In the semiconductor device and manufacturing method of the present invention the area occupied by the resistance elements that constitute the semiconductor device can be reduced because the first and second resistance elements are laminated.

In the following, the embodiments of the present invention will be explained based on figures.

### First Embodiment

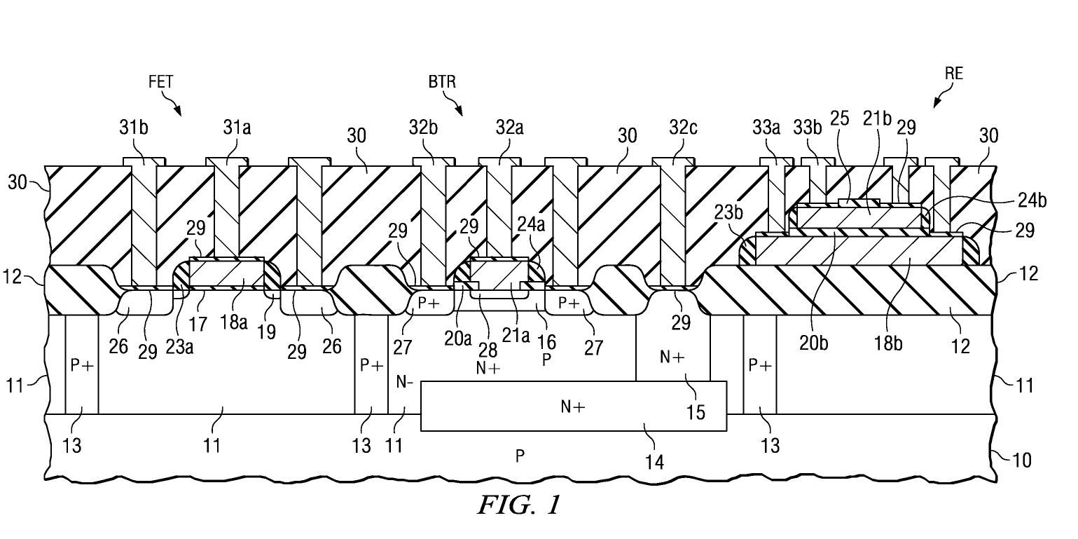

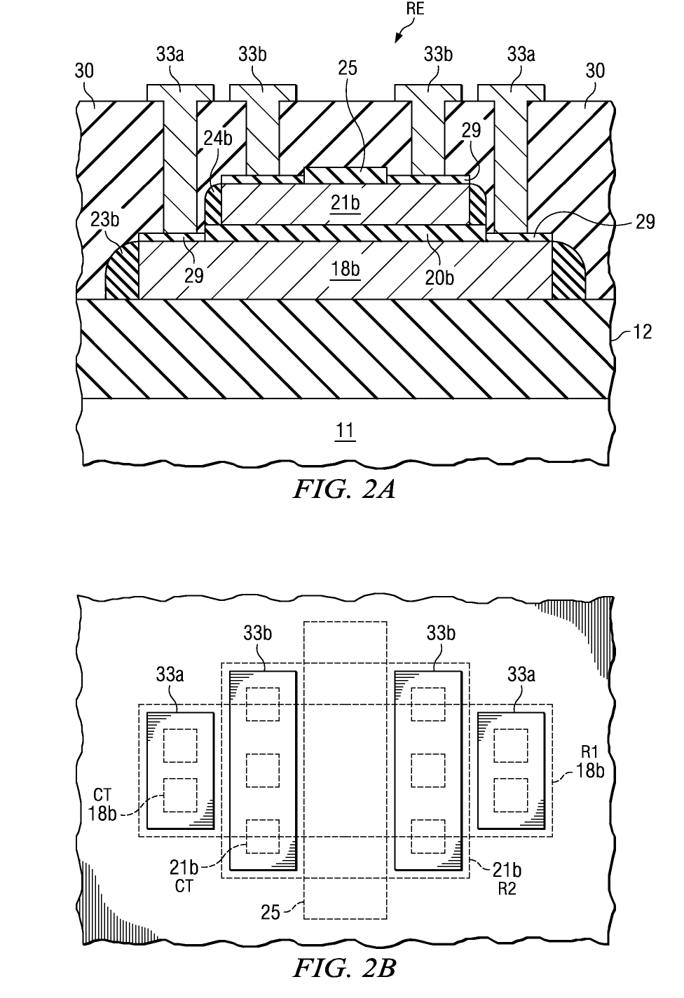

FIG. 1 is a cross section of the semiconductor device disclosed in this embodiment. FIG. 2A is an enlarged cross section of the main part (resistance element region) in FIG. 1. FIG. 2B is a corresponding plan view of the region shown in FIG. 2A.

The semiconductor device disclosed in the present embodiment has a MOS (laminated metal-insulating layer-semiconductor layer type) field-effect transistor (FET), bipolar transistor (BTR), and resistance elements (RE). For example, epitaxial semiconductor layer 11 made of n-type silicon is formed on semiconductor substrate 10 made of p-type silicon. Element separation is effected by element isolation film 12 made of silicon oxide, formed on the surface of the epitaxial semiconductor layer using the LOCOS method, etc. Element separating layer 13 made of p-type silicon is formed to reach semiconductor substrate 10 in epitaxial semiconductor layer 11 below element isolation film 12. In this way, the MOSFET (FET) region, bipolar transistor (BTR) region, and resistance element (RE) region are separated from each other.

The aforementioned MOSFET (FET) region has a channel-forming region in epitaxial semiconductor layer 11. Gate insulating film 17 is formed on the channel forming region. Gate electrode 18a is formed on gate insulating film 17. The source/drain constituted with p-type semiconductor layer 19 and p-type semiconductor layer 26 are formed adjacent to the aforementioned channel forming region in epitaxial semiconductor layer 11 on both sides of gate electrode 18a.

Sidewall insulating films 23a are formed on the two sides of gate electrode 18a on said epitaxial semiconductor layer 11. Silicide layer 29 of Ti or another metal with a high melting point is formed on the surface of gate electrode 18a and the surface of P˜type semiconductor layer 26. In this way, a P-channel type MOSFET (FET) having an insulated gate structure is formed.

The aforementioned MOSFET (FET) is covered by interlayer insulating film 30 made of silicon oxide. Contact holes are formed to reach silicide layer 29 formed on the surface of gate electrode 18a and p-type semiconductor layer 26. Upper interconnections 31a, 31b including contact plugs are formed to connect to silicide layer 29.

The figure shows a P-channel type MOSFET. It is also possible to form an N-channel type MOSFET in the region not shown in the figure to constitute a CMOS (complementary MOS). It is also possible to use an N-channel type MOSFET alone.

Also, in the aforementioned bipolar transistor (BTR) region, epitaxial semiconductor layer 11 is used as the collector region, and n-type buried layer 14 is formed at the boundary between semiconductor substrate 10 and epitaxial semiconductor layer 11. N-type plug 15 is formed from the surface of epitaxial semiconductor layer 11 to N-type buried layer 14.

Also, p-type semiconductor layer 16 acting as the intrinsic base region and p-type semiconductor layer 27 acting as the extrinsic base region are formed on the surface layer of epitaxial semiconductor layer 11 acting as the aforementioned collector region. N-type semiconductor layer 28 acting as the emitter region is formed on the surface layer of P type semiconductor layer 16 acting as the intrinsic base region. In this way, an npn type of bipolar transistor is constituted.

An insulating film 20a below the emitter-forming layer, with an opening formed to expose N+ semiconductor layer 28, is formed on said N-type semiconductor layer 28. An emitter-forming layer 21a is formed such that it contacts N-type semiconductor layer 28 via the opening formed in insulating film 20a below the emitter-forming layer. Emitter-forming layer 21a is made of polysilicon containing an electroconductive impurity used for forming N-type semiconductor layer 28 acting as the emitter region. The N-type electroconductive impurity is diffused into P-type semiconductor layer 16 through the opening in insulating film 20a below the emitter-forming layer to form N-type semiconductor layer 28.

Sidewall insulating films 24a are formed on the two sides of said emitter-forming layer 21a. Silicide layer 29 of Ti or another metal with a high melting point is formed on the surface of emitter-forming layer 21a and the surface of p-type semiconductor layer 27 and N-type plug 15. In this way, an npn type bipolar transistor (BTR) is constituted.

The aforementioned bipolar transistor (BTR) is covered by interlayer insulating film 30 made of silicon oxide. Contact holes are formed to reach the surface of emitter-forming layer 21a and silicide layer 29 of Ti or another metal with a high melting point formed on the surface of p-type semiconductor layer 27 and N-type plug 15. Upper interconnections 32a, 32b including contact plugs are formed to connect to silicide layer 29.

Also, as shown in FIGS. 1 and 2A, the polysilicon is patterned to form the first resistance element 18b on element isolation film 12 in the resistance element (RE) region. Sidewall insulating film 23b is formed on its outer periphery. The polysilicon used to form the first resistance element 18b is constituted from the layer shared with gate electrode 18a that constitutes the MOSFET (FET). Polysilicon is patterned via resistance element insulating film 20b to form the second resistance element 21b on the first resistance element 18b, except for its two end parts. Sidewall insulating film 24b is formed on its outer periphery. The polysilicon used to form the second resistance element 21b is constituted from the layer shared with emitter-forming layer 21a that constitutes the bipolar transistor (BTR).

In this case, as shown in the plan view of FIG. 2B, silicide blocking layer 25 made of silicon oxide is formed on the second resistance element 21b except for the two end parts of the second resistance element 21b. Also, the second resistance element 21b and sidewall insulating film 24b function as the silicide blocking layer with respect to the first resistance element 18b. Silicide layer 29 made of Ti or another metal with a high melting point is formed on the surface of the two end parts of the first resistance element 18b and on the surface of the two end parts of the second resistance element 21b. A resistance element (RE) comprised of laminated first resistance element R1 and second resistance element R2 is constituted in this way.

The aforementioned laminated resistance element (RE) is covered by interlayer insulating film 30 made of silicon oxide. Contact hole CT18b is formed to reach the silicide layer 29 made of Ti or another metal with a high melting point formed on the surface at the two ends of the first resistance element 18b. Upper wiring 33a including a contact plug is formed to connect to silicide layer 29. On the other hand, contact hole CT21b is formed to reach the silicide layer 29 made of Ti or another metal with a high melting point formed on the surface at the two ends of the second resistance element 21b. Upper wiring 33b including a contact plug is formed to connect to suicide layer 29. Upper interconnections 33a, 33b are connected to upper interconnections not shown in the figure.

In order to simplify the process of manufacturing the semiconductor device disclosed in the aforementioned embodiment, the first resistance element 18b is formed by the layer shared with the gate electrode of the field-effect transistor, for example. On the other hand, the second resistance element 21b is formed by the layer shared with the second emitter-forming layer doped with an electroconductive impurity and used to form the emitter of the bipolar transistor. In addition, the first and second resistance elements are laminated. In this way, the area occupied by the resistance elements that constitute the semiconductor device can be reduced.

In the semiconductor device disclosed in the aforementioned embodiment, the first and second resistance elements can be used as independent resistance elements or can be connected to each other in series or in parallel to obtain a desired sheet resistance.

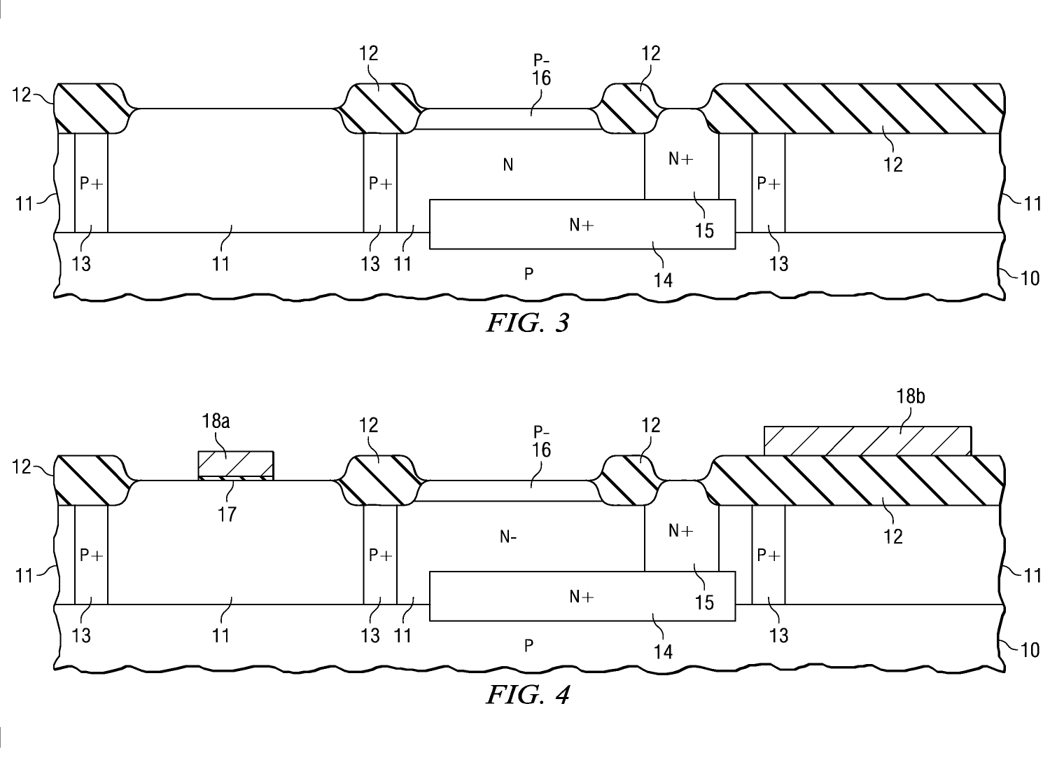

In the following, the method for manufacturing the semiconductor device disclosed in this embodiment will be explained based on FIGS. 3-10. First, as shown in FIG. 3, an N type epitaxial semiconductor layer 11 is formed by means of epitaxial growth on a P-type semiconductor substrate 10. In this case, semiconductor substrate 10 is doped in advance with an N-type electroconductive impurity in the formation region of the bipolar transistor. After epitaxial semiconductor layer 11 is formed, the impurity is diffused into semiconductor substrate 10 and epitaxial semiconductor layer 11 to form N˜type buried layer 14. Also, the ions of a P-type electroconductive impurity are injected in a pattern into the element separating region to form element separating layer 13, and element isolation film 12 made of silicon oxide is formed using the LOCOS method.

If necessary, the ions of a channel impurity are injected into the MOSFET forming region in the active region separated by the element isolation film. Also, the ions of an N-type and a P-type electroconductive impurities are injected into the bipolar transistor forming region to form N-type plug 15 and P-type semiconductor layer 16.

Subsequently, as shown in FIG. 4, gate insulating film 17 is formed on the surface of epitaxial semiconductor layer 11 in the active region, using the thermal oxidization method, for example. Polysilicon is then deposited using a CVD (chemical vapor deposition) method, and a resist film in the pattern of the gate electrode is formed by photolithography. After that, patterning is performed by means of RIE (reactive ion etching) or another etching method to form gate electrode 18a. In this step, part of the pattern of the polysilicon used to form gate electrode 18a is left over on element isolation film 12 to form the first resistance element 18b.

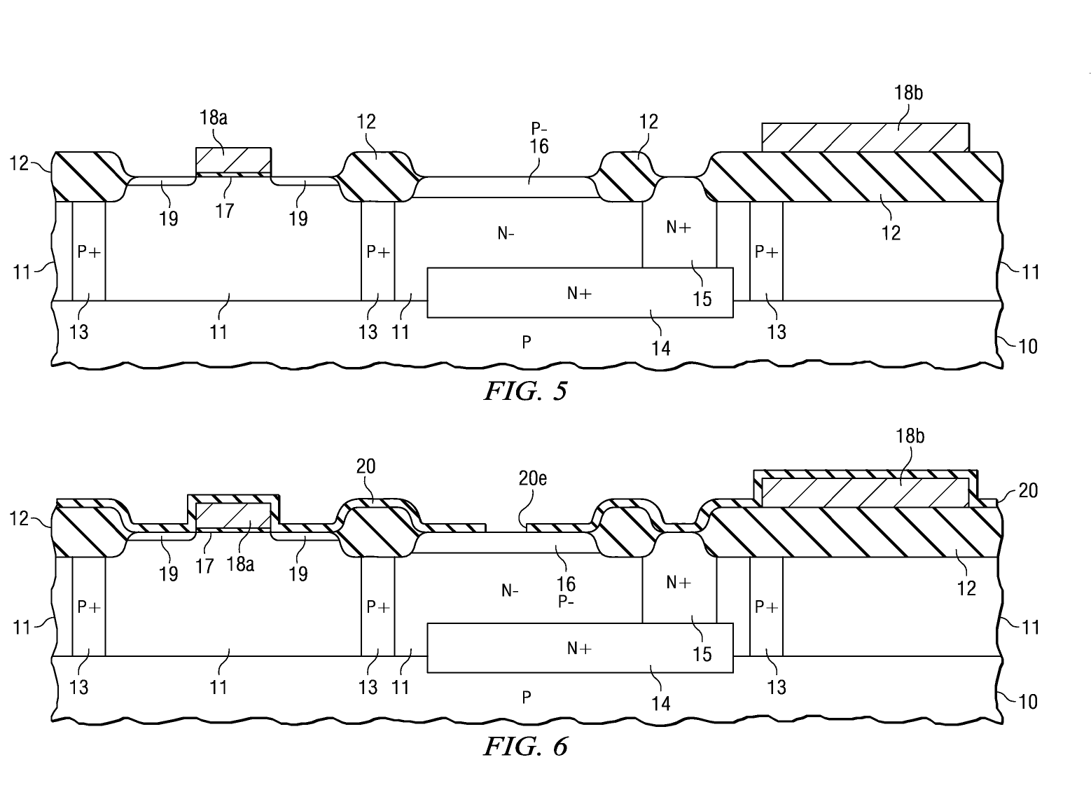

Subsequently, as shown in FIG. 5, a resist film is formed in a pattern that opens at the MOSFET forming region. With gate electrode 18a being used as a mask, the ions of a P-type electroconductive impurity are injected to form P-type semiconductor layer 19 that constitutes the source/drain.

Subsequently, as shown in FIG. 6, silicon oxide is deposited on the entire surface by means of CVD to form gate/emitter isolation film 20 that separates the polysilicon constituting gate electrode 18a from the emitter-forming layer formed in the next step. Said gate/emitter isolation film 20 is formed to also cover the first resistance element 18b.

A resist film is formed by means of photolithography in a pattern that opens at the emitter-forming region, followed by RIE or other etching to form opening 20e used to form the emitter in gate/emitter isolation film 20.

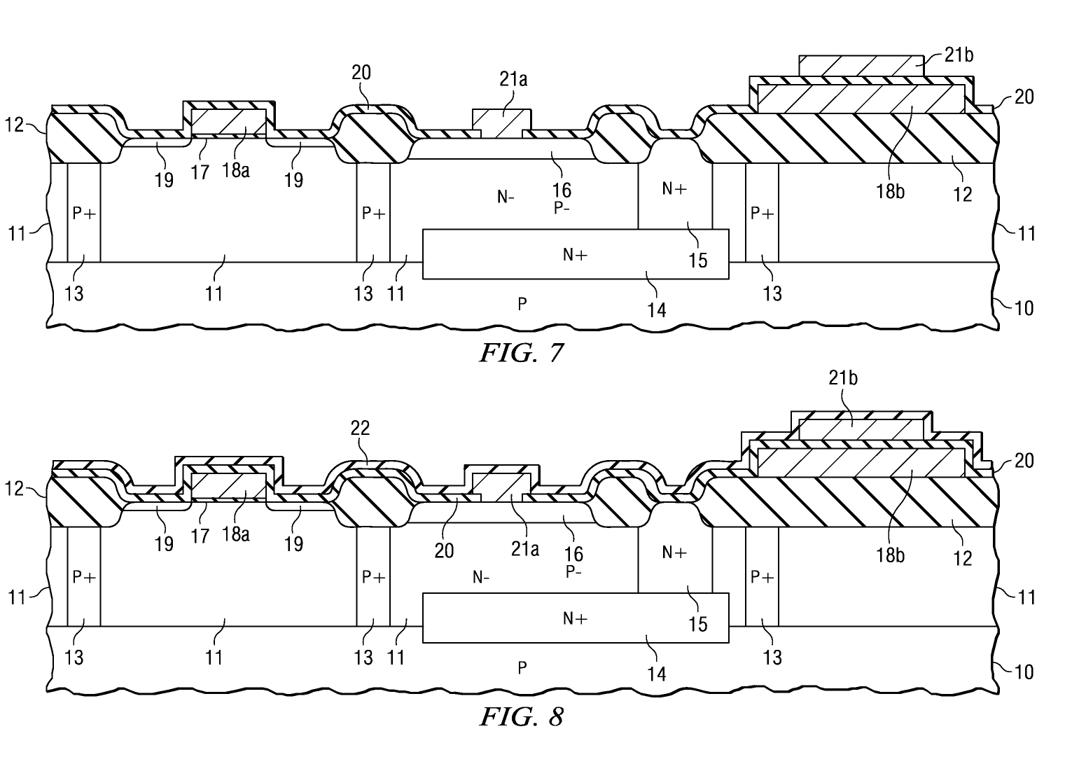

Subsequently, as shown in FIG. 7, polysilicon is deposited by CVD, and a resist film is formed by photolithography in the pattern of the emitter-forming layer. Then, patterning is performed by RIE or another etching method to form emitter-forming layer 21a in a pattern that blocks opening 20e used to form the emitter. In this step, part of the pattern of the polysilicon used for forming emitter-forming layer 21a is left remaining on gate/emitter isolation film 20 on the first resistance element 18b to form the second resistance element 21b.

Subsequently, as shown in FIG. 8, silicon oxide is deposited on the entire surface by CVD to form film 22 for sidewall insulating.

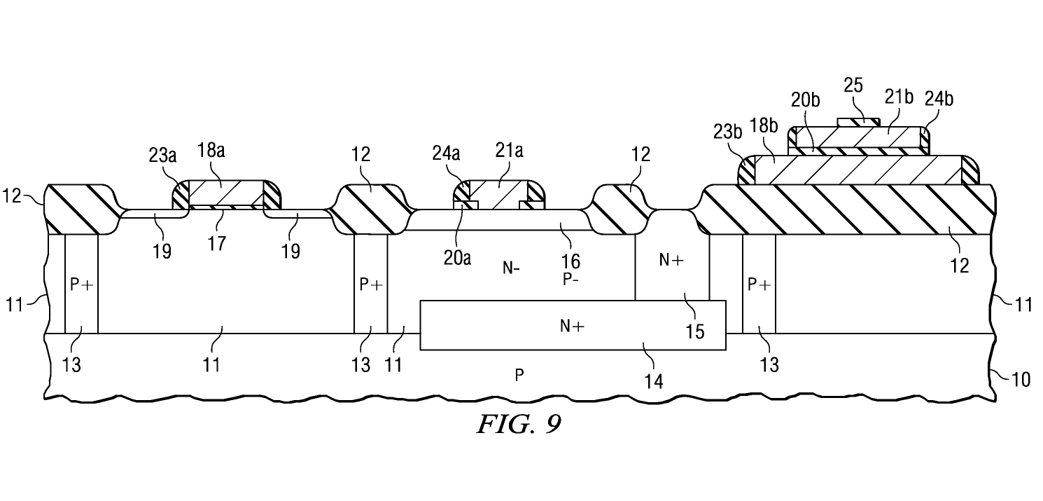

Subsequently, as shown in FIG. 9, etchback is performed on the entire surface with respect to gate/emitter isolation film 20 and film 22 for sidewall insulating. Part of gate/emitter isolation film 20 and film 22 for sidewall insulating are left remaining on the two sides of gate electrode 18a to form sidewall insulating film 23a. The width of sidewall insulating film 23a can be adjusted by adjusting film 22 for sidewall insulating. In this case, sidewall insulating film 23b is formed on the outer periphery of the first resistance element 18b at the same time.

On the other hand, part of gate/emitter isolation film 20 and film 22 for sidewall insulating is left remaining below and on the two sides of emitter-forming layer 21a to form insulating film 20a below the emitter-forming layer and sidewall insulating film 24a. In this case, sidewall insulating film 24b is formed on the outer periphery of the second resistance element 21b at the same time. Also, silicide blocking layer 25 is formed by leaving part of film 22 for sidewall insulating to cover the second resistance element 21b except for its two end parts.

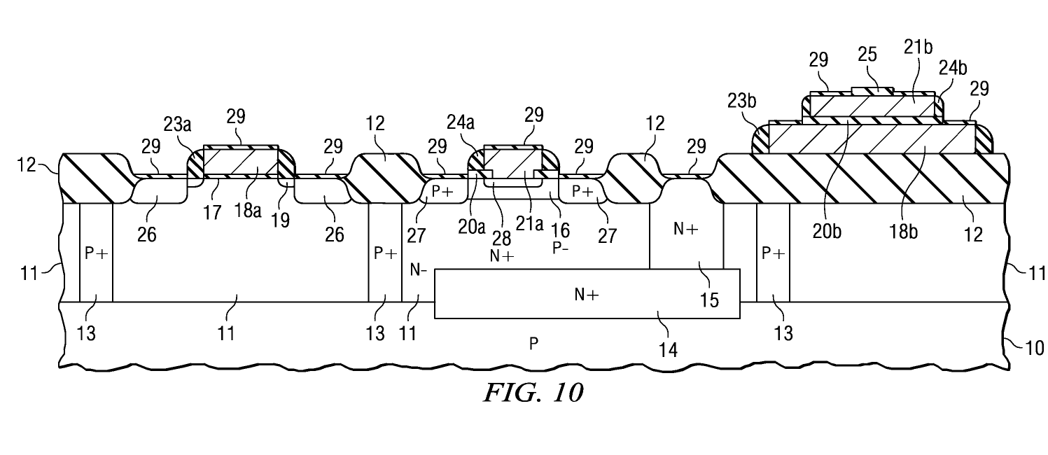

Subsequently, as shown in FIG. 10, a resist film is formed in a pattern that opens at the MOSFET-forming region. With gate electrode 18a and sidewall insulating film 23a being used as mask, the ions of a P-type electroconductive impurity are injected to form p-type semiconductor layer 26 that constitutes the source/drain to connect to P-type semiconductor layer 19. P-type semiconductor layer 27 acting as the extrinsic base extracting region is formed in the bipolar transistor forming region in the same way as described above.

Also, an N-type electroconductive impurity is diffused from emitter-forming layer 21a into P type semiconductor layer 16 by means of heat treatment, forming N-type semiconductor layer 28 as the emitter region.

In addition, by siliciding the silicon exposed on the surface in a self-aligning manner, silicide layer 29 made of Ti or another metal with a high melting point is formed on the surface of the two end parts of the first resistance element 18b and on the surface of the two end parts of the second resistance element 21b in the resistance element forming region, on the surface of gate electrode 18a and the surface of p-type semiconductor layer 26 in the MOSFET forming region, on the surface of emitter-forming layer 21a and the surface of p-type semiconductor layer 27, and on N-type plug 15 in the bipolar transistor forming region. The MOSFET (FET), bipolar transistor (BTR), and resistance element (RE) are formed in this way.

In the subsequent process, for example, silicon oxide is deposited on the entire surface by CVD to form interlayer insulating film 30. Contact holes are formed to reach the silicide layer 29 formed on the surface of gate electrode 18a, the surface of p-type semiconductor layer 26, the surface of emitter-forming layer 21a, the surface of p-type semiconductor layer 27 and N-type plug 15, the surface of the two end parts of the first resistance element 18b and the surface of the two end parts of the second resistance element 21b, whereupon upper interconnections 31a, 31b, 32b, 32b, 33a, 33b including contact plugs are formed. In this way, the semiconductor device with the configuration shown in FIG. 1 can be manufactured.

By using the semiconductor device manufacturing method disclosed in the aforementioned embodiment, the first resistance element 18a is formed by the layer shared with the gate electrode of the field-effect transistor. On the other hand, the second resistance element 21a is formed by the layer shared with the second emitter-forming layer containing an electroconductive impurity used to form the emitter of the bipolar transistor. The manufacturing process can therefore be simplified. Also, the area occupied by the resistance element that constitutes the semiconductor device can be reduced by laminating the first and second resistance elements.

### Second Embodiment

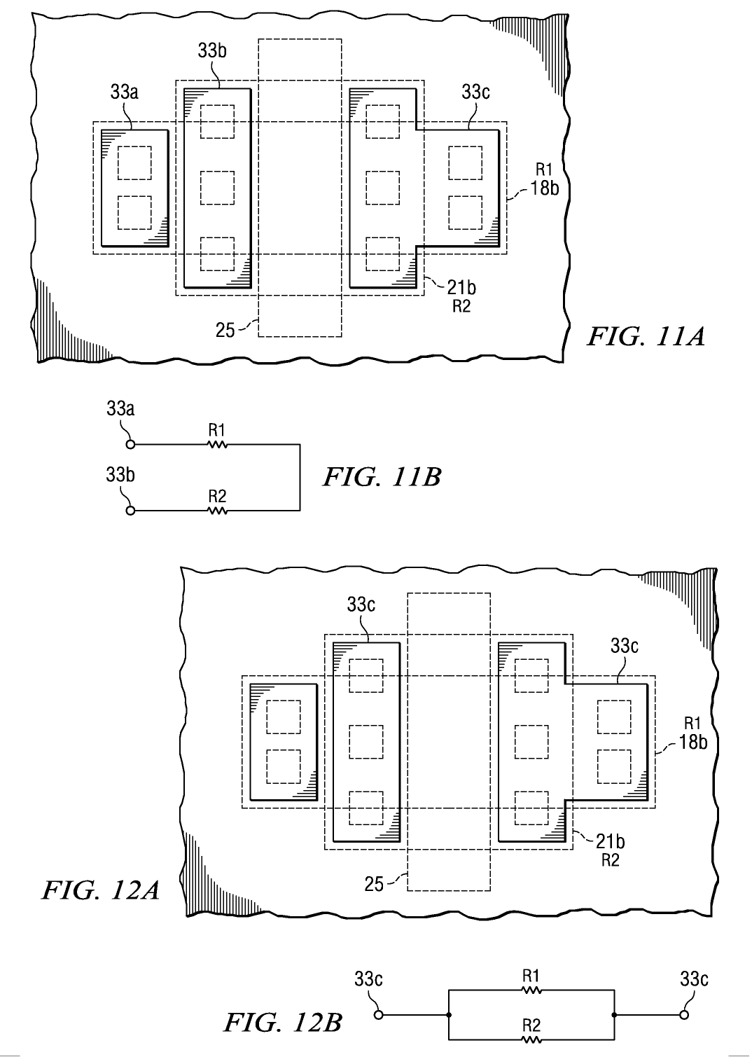

FIG. 11A is a plan view illustrating a resistance element formed by connecting the first and second resistance elements, laminated as described above, in series. FIG. 11B is the equivalent circuit diagram.

Upper interconnections 33a, 33b are formed independently as terminals at one end of the first resistance element 18b R1 and the second resistance element 21b R2. Upper wiring 33c connecting the first resistance element 18b R1 and the second resistance element 21b R2 is formed at the other end.

### Third Embodiment

FIG. 12A is a plan view illustrating a resistance element formed by connecting the first and second resistance elements, laminated as described above, in parallel with each other. FIG. 12B is the equivalent circuit diagram.

An upper wiring 33c connecting the first resistance element 18b R1 and second resistance element 21b R2 is formed at one end of the first resistance element 18b R1 and second resistance element 21b R2. Another upper wiring 33c connecting the first resistance element 18b R1 and second resistance element 21b R2 is formed at the other end. These upper interconnections 33c are used as terminals.

### Fourth Embodiment

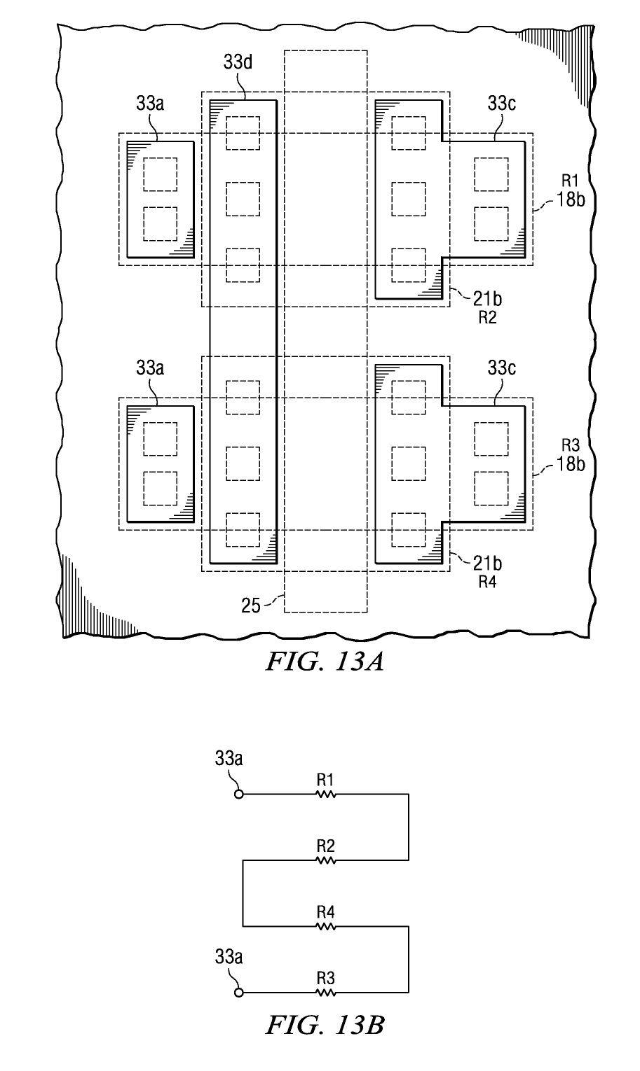

FIG. 13A is a plan view illustrating a resistance element formed by connecting the first and second resistance elements, laminated as described above, in series with a third resistance element and fourth resistance element laminated adjacent to them. FIG. 13B is the equivalent circuit diagram.

The first resistance element 18b R1 and second resistance element 21b R2 are laminated. The third resistance element 18b R3 and fourth resistance element 21b R2 are laminated adjacent to them in the same way as the first resistance element 18b R1 and the second resistance element 21b R2.

An upper wiring 33c connecting the first resistance element 18b R1 and second resistance element 21b R2 is formed at one end of the first resistance element 18b R1 and second resistance element 21b R2. Another upper wiring 33c connecting the third resistance element 18b R3 and fourth resistance element 21b R4 are formed at one end of the third resistance element 18b R3 and fourth resistance element 21b R4.

Also, upper wiring 33d connecting the second resistance element 21b R2 and fourth resistance element 21b R4 and upper wiring 33a connecting the first resistance element 18b R1 and third resistance element 18b R3 are formed independently at the other end.

### Fifth Embodiment

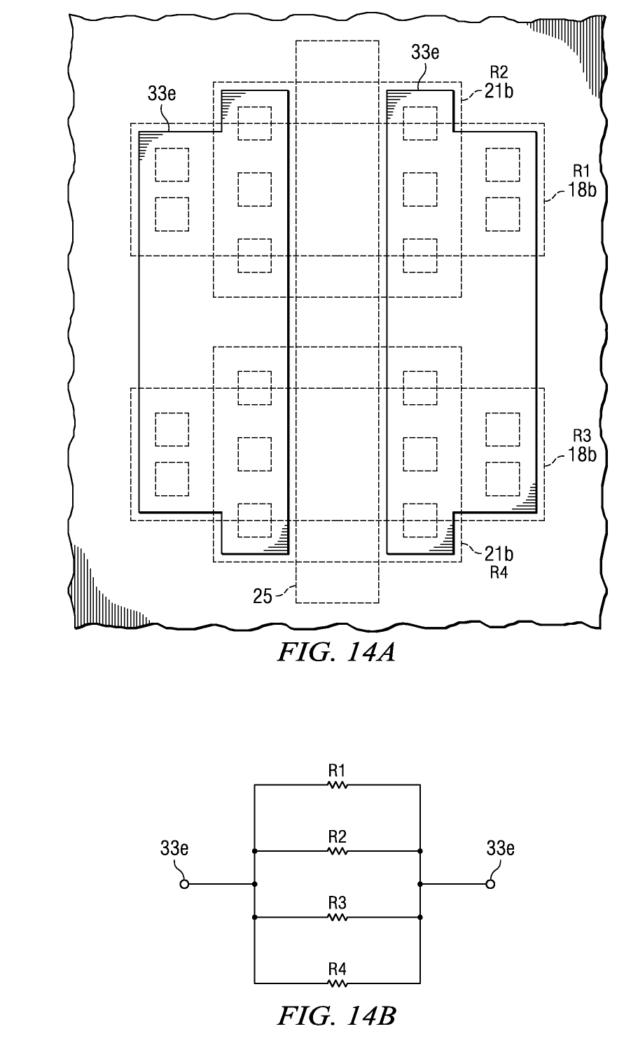

FIG. 14A is a plan view illustrating a resistance element formed by connecting the first and second resistance elements, laminated as described above, in parallel with a third resistance element and fourth resistance element laminated adjacent to them. FIG. 14B is the equivalent circuit diagram.

As in the fourth embodiment, the first resistance element 18b R1 and second resistance element 21b R2 are laminated. The third resistance element 18b R3 and fourth resistance element 21b R2 are laminated adjacent to them in the same way as the first resistance element 18b R1 and second resistance element 21b R2.

An upper wiring 33e connecting the aforementioned first resistance element 18b R1, the second resistance element 21b R2, the third resistance element 18b R3, and the fourth resistance element 21b R4 is formed at one end. Another upper wiring 33e connecting the first resistance element 18b R1, the second resistance element 21b R2, the third resistance element 18b R3, and the fourth resistance element 21b R4 is formed at the other end.

### Sixth Embodiment

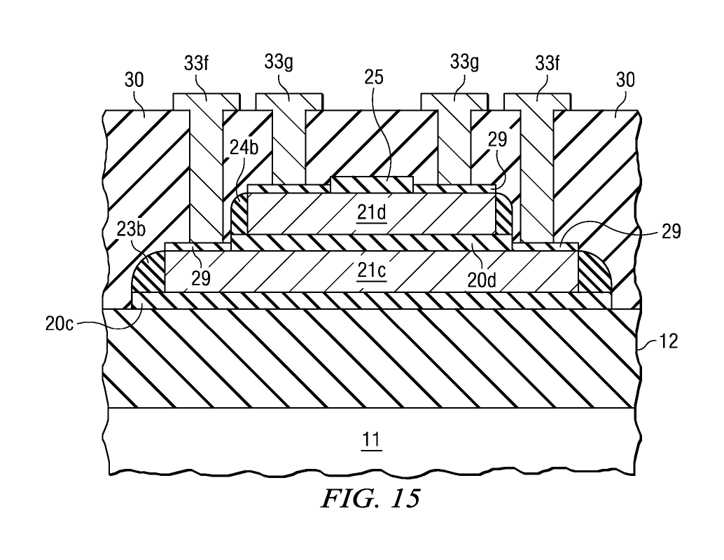

FIG. 15 is an enlarged cross section of the main part (resistance element region) of the semiconductor device disclosed in this embodiment.

Polysilicon is patterned to form the first resistance element 21c on element isolation film 12. The polysilicon that forms the first resistance element 21c is constituted from the layer shared with the emitter-forming layer (not shown in the figure) that constitutes the first bipolar transistor of npn type, for example. Gate/emitter isolation film 20c made of silicon oxide is left remaining below the first resistance element 21c.

Polysilicon is patterned through resistance element insulating film 20d to form the second resistance element 21d on the first resistance element 21c except at the two end parts. The polysilicon that forms the second resistance element 21d is constituted from the layer shared with the emitter-forming layer (not shown in the figure) that constitutes the second bipolar transistor of pnp type.

The rest of the configuration is the same as that described in the first embodiment. The first bipolar transistor of npn type and the second bipolar transistor of pnp type are formed in the region not shown in the figure. It is also possible to form a CMOS transistor, etc.

As described above in the first embodiment, the resistance element constituted with the layer shared with the gate electrode of the CMOS transistor is laminated with the resistance element constituted with the layer shared with the emitter-forming layer of the bipolar transistor. This, however, is not the only choice. It is also possible to laminate a resistance element formed with a layer shared with the emitter-forming layer of a pnp type bipolar transistor and a resistance element formed with a layer shared with the emitter-forming layer of an npn type bipolar transistor. In this case, as in the first embodiment, the first resistance element 18a is formed by the layer shared with the gate electrode of the field-effect transistor in order to simplify the manufacturing process. On the other hand, the second resistance 21a is formed by the layer shared with the second emitter-forming layer containing an electroconductive impurity and used to form the emitter of the bipolar transistor. Also, the area occupied by the resistance element that constitutes the semiconductor device can be reduced by laminating the first and second resistance elements.

This embodiment is also applicable to the second through fifth embodiments. The present invention is not limited by the explanation given above. For example, it is also possible to form the first resistance element with the layer shared with the layer that constitutes the bipolar transistor, and to form the second resistance element with the layer shared with the layer that constitutes the MOSFET.

When either the first or the second resistance element is formed by the layer shared with the layer that constitutes the MOSFET and the other resistance element is formed by the layer shared with the layer that constitutes the bipolar transistor, the bipolar transistor can be of either npn or pnp type.

Various modifications can be made as long as they do not deviate from the main idea of the present invention. The semiconductor device of the present invention can be used for semiconductor devices having transistors and resistance elements. The semiconductor device manufacturing method of the present invention can be used to manufacture semiconductor devices having transistors and resistance elements.

1. A semiconductor device comprising:
an insulating film formed on a substrate,
a first resistance element formed on the insulating film,
a second resistance element laminated on the first resistance element.

2. The semiconductor device described in claim 1, wherein transistors are formed in the semiconductor region of the said substrate, and the first and second resistance elements include layers shared with the respective layers that constitute the transistors.

3. The semiconductor device described in claim 2, wherein:
said transistors comprise a field-effect transistor and a bipolar transistor formed in the semiconductor region of the substrate;
the first resistance element includes a layer shared with the layer that constitutes the gate electrode of the field-effect transistor;
the second resistance element includes a layer shared with an emitter-forming layer doped with an electroconductive impurity and used to form the emitter of the bipolar transistor.

4. The semiconductor device described in claim 2, wherein:
a first bipolar transistor and a second bipolar transistor are formed in the semiconductor region of the aforementioned substrate;
the first resistance element includes a layer shared with the first emitter-forming layer doped with an electroconductive impurity and used to form the emitter of the first bipolar transistor;
the aforementioned second resistance element includes a layer shared with the second emitter-forming layer doped with an electroconductive impurity and used to form the emitter of the second bipolar transistor.

5. A semiconductor device manufacturing method comprising the steps of:
forming an insulating film on a substrate,
forming a first resistance element on the insulting film, and
laminating a second resistance element on the first resistance element.

6. The semiconductor device manufacturing method described in claim 5 characterized by the fact that the method also comprises a step for forming transistors in the semiconductor region of the aforementioned substrate, and wherein, in the steps for forming the aforementioned first and second resistance elements, the resistance elements are formed to include layers shared with the respective layers constituting the aforementioned transistors.

7. The semiconductor device manufacturing method described in claim 6 wherein:
the step for forming the aforementioned transistors includes a step for forming a field-effect transistor in the semiconductor region of the aforementioned substrate and a step for forming a bipolar transistor in the aforementioned semiconductor region;
in the step for forming the aforementioned first resistance element, the resistance element is formed to include a layer shared with the layer constituting the gate electrode of the aforementioned field-effect transistor;
in the step for forming the aforementioned second resistance element, the resistance element is formed to include a layer shared with the emitter-forming layer doped with an electroconductive impurity and used to form the emitter of the aforementioned bipolar transistor.

8. The semiconductor device manufacturing method described in claim 6 wherein:
the method also has a step for forming a first bipolar transistor in the semiconductor region of the aforementioned substrate and
a step for forming a second bipolar transistor in the aforementioned semiconductor region;
in the step for forming the first resistance element, the resistance element is formed to include a layer shared with the layer constituting the first emitter-forming layer doped with an electroconductive impurity and used to form the emitter of the first bipolar transistor;
in the step for forming the second resistance element, the resistance element is formed to include a layer shared with the layer constituting the second emitter-forming layer doped with an electroconductive impurity and used to form the emitter of the second bipolar transistor.
